(19) United States
(12) Patent Application Publication
(10) Pub. No.: US 2025/0038017 A1
(43) Pub. Date: Jan. 30, 2025

(54) RESIN SEALING DEVICE

(71) Applicant: APIC YAMADA CORPORATION, Nagano (JP)

(72) Inventor: Masahiko Fujisawa, Nagano (JP)

(73) Assignee: APIC YAMADA CORPORATION, Nagano (JP)

(21) Appl. No.: 18/707,161

(22) PCT Filed: Aug. 23, 2022
(86) PCT No.: PCT/JP2022/031652

§ 371 Date: May 2, 2024

(30) Foreign Application Priority Data
Jan. 19, 2022 (JP) 2022-006076

(51) Int. Cl. H01L 21/67

(52) U.S. Cl. CPC H01L 21/67126

(57) ABSTRACT

A resin sealing device seals a workpiece with resin and processes it into a molded product using a press device including a sealing mold having an upper die and a lower die. The resin sealing device includes a loader that reciprocates in the left-right direction along a guide and that conveys the workpiece and the molded product, wherein the loader has: an in-loader section that is configured so as to be able to move in the front-rear direction and that carries the workpiece into the sealing mold; and an out-loader section that is configured so as to be able to move in the front-rear direction and that carries the molded product out of the sealing mold, the in-loader section and the out-loader section being arranged in parallel in the left-right direction.

### TECHNICAL FIELD

The present invention relates to a resin sealing device.

### RELATED ART

As examples of a resin sealing device in which a workpiece having an electronic component mounted on a base material is sealed with sealing resin (hereinafter sometimes simply referred to as “resin”) and processed into a molded product, there are known those using a transfer molding method and those using a compression molding method.

The transfer molding method is the following technique. A pot is provided that supplies a predetermined amount of resin to a pair of sealing areas (cavities) provided in a sealing mold configured to include an upper die and a lower die. A workpiece is arranged in a position corresponding to each of the sealing areas, clamped by the upper die and the lower die, and the resin is poured from the pot into the cavities, thereby performing resin sealing. The compression molding method is the following technique. A predetermined amount of resin is supplied to a sealing area (cavity) provided in a sealing mold configured to include an upper die and a lower die, a workpiece is arranged in the sealing area, and a clamping operation is performed by the upper die and the lower die, thereby performing resin sealing (see Patent Document 1: Japanese Patent Laid-open No. 2019-145550). As an example, in the case of using a sealing mold in which a cavity is provided in the upper die, a technique is known in which resin is collectively supplied to a center position on the workpiece for molding. On the other hand, in the case of using a sealing mold in which a cavity is provided in the lower die, a technique is known in which a film covering a mold surface including the cavity and resin are supplied for molding.

### PRIOR-ART DOCUMENTS

### Patent Documents

Patent Document 1: Japanese Patent Laid-open No. 2019-145550

### SUMMARY OF THE INVENTION

### Problems to Be Solved by the Invention

Conventional resin sealing devices have the following problems. That is, in a resin sealing device in which a workpiece having a relatively large outer shape (for example, 600 mm²) is sealed with resin, when a product (molded product) after molding is carried out of the sealing mold and an object (workpiece) to be molded next is carried in, the following processes are usually performed. Specifically, in the case of a single loader, the following processes are performed. The molded product is carried out of the sealing mold and conveyed to the next process stage, and then the next workpiece is carried into the sealing mold using the loader again. Hence, there is a problem that, until the molded product is conveyed to the next process stage, the workpiece cannot be carried into the sealing mold and molding (resin sealing) cannot be performed, and productivity may be reduced. Particularly, if two or more press units equipped with the sealing mold are installed, a conveyance distance of the molded product (and workpiece) is increased, and a significant reduction in productivity may occur. On the other hand, in the case of two loaders (that is, an in-loader and an out-loader are separately and independently configured), while reduction in productivity is suppressed, an internal structure of the device may become complex and the device cost may be increased.

With respect to the above problems, it has been considered to provide a workpiece holding mechanism and a molded product holding mechanism separately in a single loader in order to suppress the reduction in productivity. For example, as shown in Patent Document 1, a configuration has been considered in which the workpiece holding mechanism and the molded product holding mechanism are provided side by side in a front-rear direction (direction that coincides with a carry-in and carry-out direction to and from the sealing mold) of the loader. However, a new problem may arise as follows. Since the loader may have a shape long in the front-rear direction, particularly, when a large workpiece is assumed, an overhang may become long on a cantilever support structure, and the size may be increased in order to ensure strength. On the other hand, a configuration has been considered in which the workpiece holding mechanism and the molded product holding mechanism are respectively provided on an upper surface and a lower surface of the loader. However, since the loader may have a shape thick in an up-down direction, a separation distance between the upper die and the lower die is increased, and a new problem may arise that it takes time to open and close the mold.

### Means for Solving the Problems

The present invention has been made in view of the above circumstances, and aims to provide a resin sealing device which makes it possible to shorten takt time in a series of processes of carrying a workpiece into a sealing mold and carrying a molded product out of the sealing mold using a loader, improve productivity, and simplify a device configuration.

The present invention solves the above-mentioned problems by a solution as described below as an embodiment.

A resin sealing device according to the present invention is a resin sealing device in which a workpiece is sealed with resin and processed into a molded product using a press device including a sealing mold that includes an upper die and a lower die. The resin sealing device includes a loader that reciprocates in a left-right direction along a guide and conveys the workpiece and the molded product. The loader includes: an in-loader section, configured to be movable in a front-rear direction and carrying the workpiece into the sealing mold; and an out-loader section, configured to be movable in the front-rear direction and carrying the molded product out of the sealing mold. The in-loader section and the out-loader section are required to be arranged in parallel along the left-right direction.

According to this, the molded product can be carried out of the sealing mold by the out-loader section while the workpiece is held in the in-loader section. After that, by simply moving the in-loader section a little to a position where it coincides with the sealing mold, the workpiece can be carried into the sealing mold by the in-loader section. Accordingly, takt time in the process of carrying in the workpiece and carrying out the molded product can be shortened.

The in-loader section preferably includes, on a lower surface, a workpiece holder that holds the workpiece. The out-loader section preferably includes, on a lower surface, a molded product holder that holds the molded product. According to this, in a device configuration including the sealing mold in which a cavity is provided in the upper die and the workpiece holder is provided in the lower die, a configuration can be realized in which the workpiece holder that holds the workpiece and the molded product holder that holds the molded product are arranged in parallel in a single loader.

The resin sealing device further includes a workpiece heater that preheats the workpiece. The workpiece heater is arranged in a predetermined position along the guide and below the loader. The loader is preferably configured so that the workpiece held by the workpiece holder of the in-loader section is exposed toward the workpiece heater. According to this, it is possible to preheat the workpiece by the workpiece heater while the workpiece is held by the workpiece holder arranged on the lower surface of the in-loader section.

The loader preferably includes: a first lifting mechanism, lifting and lowering the in-loader section; and a pressing mechanism, pressing the workpiece held by the workpiece holder of the in-loader section against the workpiece heater. According to this, since a workpiece or the like composed of a glass panel, in particular, can be preheated while pressure is applied thereto, breakage of the workpiece can be prevented.

The pressing mechanism is preferably configured so that a pressure that presses the workpiece against the workpiece heater is variable stepwise during pressing. According to this, when a workpiece or the like composed of a glass panel, in particular, is preheated, breakage of the workpiece can further be prevented.

The loader preferably includes: a second lifting mechanism, lifting and lowering the out-loader section; and one motor, driving both the first lifting mechanism and the second lifting mechanism. According to this, since a single motor serving as a drive source for the first lifting mechanism and the second lifting mechanism can be shared, the structure can be simplified and the device cost can be reduced.

There are arranged two press devices. There is arranged one loader. The resin sealing device includes a control part that controls operation of the press device and the loader. Preferably, the control part performs control such that a resin sealing process in each of the two press devices is performed in a temporally staggered manner, and carry-in of the workpiece and carry-out of the molded product with respect to the two press devices are performed using the one loader. According to this, while molding is performed by one press device, carry-in of the workpiece and carry-out of the molded product in another press device can be performed by a single loader. Thus, a configuration for separately and independently driving two loaders is not necessary, the device can be simplified and the cost can be reduced.

### Effects of the Invention

According to the present invention, particularly by improving the efficiency in carry-in of the workpiece and carry-out of the molded product using a loader, the takt time in a series of resin sealing processes can be shortened and productivity can be improved. A device configuration can be simplified.

### BRIEF DESCRIPTION OF THE DRAWINGS

FIG. 1 is a plan view showing an example of a resin sealing device according to an embodiment of the present invention.

FIG. 2 is a front sectional view showing an example of a sealing mold of the resin sealing device shown in FIG. 1.

FIG. 3 is a front sectional view showing an example of a loader of the resin sealing device shown in FIG. 1.

### DESCRIPTION OF THE EMBODIMENTS

### Overall Structure

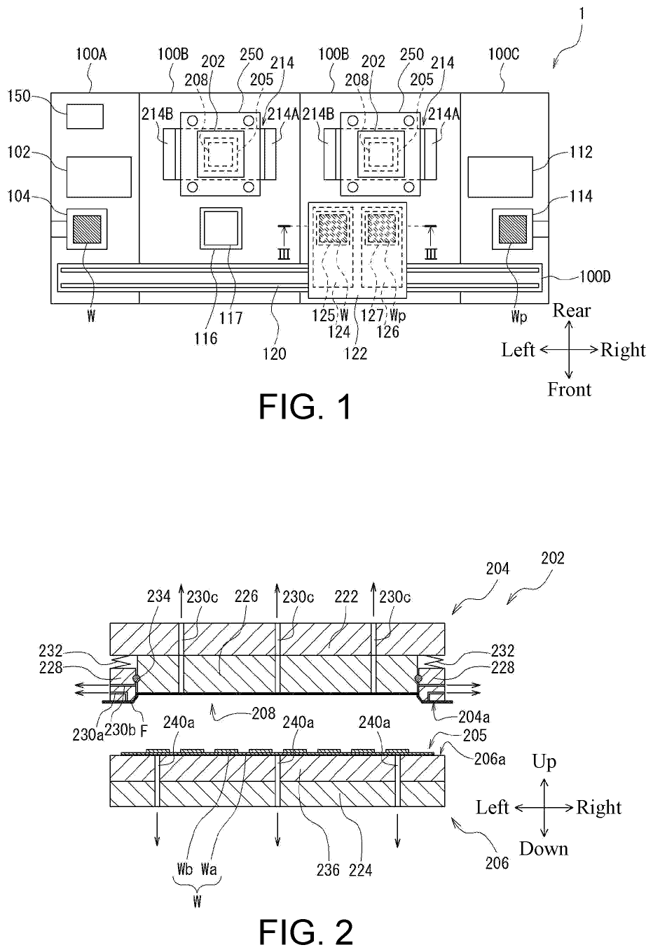

An embodiment of the present invention will be hereinafter described in detail with reference to the drawings. FIG. 1 is a plan view (schematic view) showing an example of a resin sealing device 1 according to the present embodiment. For convenience of description, a front-rear direction, a left-right direction and an up-down direction in the resin sealing device 1 may be described using arrows in the drawings. In all the drawings for describing each embodiment, members having the same functions are assigned the same reference numerals, and repeated description thereof may be omitted.

The resin sealing device 1 according to the present embodiment is a device in which a workpiece (molded product) W is sealed with resin using a sealing mold 202 that includes an upper die 204 and a lower die 206. Hereinafter, as an example of the resin sealing device 1, a compression molding device is described in which the workpiece W is held by the lower die 206, a cavity 208 (including a portion of a mold surface 204a) provided in a corresponding arrangement in the upper die 204 is covered with a release film (hereinafter sometimes simply referred to as “film”) F, the upper die 204 and the lower die 206 are clamped, and the workpiece W is sealed with resin R.

First, the workpiece W to be molded has a configuration in which a plurality of electronic components Wb are mounted in a matrix on a base material Wa. More specific examples of the base material Wa include a plate-like member, such as a resin substrate, a ceramic substrate, a metal substrate, a carrier plate, a lead frame, and a wafer, formed in a rectangular shape, a circular shape or the like. Examples of the electronic component Wb include a semiconductor chip, a MEMS chip, a passive element, a heat sink, a conductive member, and a spacer. However, the present invention is not limited thereto.

Examples of a method for mounting the electronic component Wb on the base material Wa include a mounting method by wire bonding mounting or by flip-chip mounting. Alternatively, in the case of a configuration in which the base material (carrier plate made of glass or metal) Wa is peeled from a molded product Wp after resin sealing, there is also a method in which the electronic component Wb is attached using an adhesive tape having thermal releasability or using ultraviolet curable resin that is cured by ultraviolet irradiation.

On the other hand, as an example of the resin R, liquid thermosetting resin (for example, filler-containing epoxy-based resin) is used. The resin R is not limited to the above state, and may be in any other state (shape) such as granulated (used as a general term for granular, pulverized, powdered or the like), plate-like, or sheet-like, or may be any resin other than epoxy-based thermosetting resins.

As an example of the film F, a film material having excellent heat resistance, ease of peeling, flexibility, and extensibility, such as, for example, polytetrafluoroethylene (PTFE), polytetrafluoroethylene polymer (ETFE), PET, FEP, fluorine-impregnated glass cloth, polypropylene, or polyvinylidine chloride, is suitably used. In the present embodiment, a roll-shaped film is used as the film F. As another example, a configuration (not shown) may be adopted in which a strip-shaped film is used.

Subsequently, an overview of the resin sealing device 1 according to the present embodiment is described. As shown in FIG. 1, the resin sealing device 1 includes, as main configurations: a workpiece unit 100A, mainly supplying (including feeding from the previous process) the workpiece W to be sealed with resin and the resin R; a press unit 100B, mainly sealing the workpiece W with resin and processing it into the molded product Wp; and a molded product unit 100C, mainly storing (including delivery to the next process) the molded product Wp after resin sealing. The resin sealing device 1 further includes a conveyance mechanism 100D that moves between each unit and conveys the workpiece W, the resin R, and the molded product Wp. A control part 150 that controls operation of each mechanism is arranged in the workpiece unit 100A. However, the control part 150 may be configured to be arranged in any other unit.

An overall configuration of the resin sealing device 1 can be changed by changing a configuration of a unit. For example, while the configuration shown in FIG. 1 is an example in which two press units 100B are installed, it is possible to install only one press unit 100B, or install three or more press units 100B. It is also possible to additionally install other units (none shown).

### Workpiece Unit

Subsequently, the workpiece unit 100A included in the resin sealing device 1 is described in detail.

As an example, the workpiece unit 100A includes: a workpiece stocker 102, used for accommodating the workpiece W; and a supply table 104, on which the workpiece W is placed. Accordingly, the workpiece W is extracted from the workpiece stocker 102 using a known pusher or the like (not shown), and is placed on the supply table 104. A known stack magazine, slit magazine, or the like may be used for the workpiece stocker 102, which is able to collectively accommodate a plurality of workpieces W.

Alternatively, as another example, a configuration (not shown) may be adopted in which the workpiece W is conveyed from another unit performing the previous process and is placed on the supply table 104 using a moving device (such as a conveyor).

The workpiece unit 100A (or another unit) is provided with a dispenser (not shown) that supplies the resin R onto an upper surface of the workpiece W placed on the supply table 104 (or a resin spraying table may be separately provided). The workpiece W, while having the resin R placed on the upper surface thereof, is conveyed to the sealing mold 202 by a loader 122. However, the present invention is not limited thereto. A configuration (not shown) may be adopted including a resin loader that directly carries the resin R into the sealing mold 202 separately from the workpiece W.

Configurations (none shown) may be adopted including an inspection mechanism that inspects an appearance of the workpiece W in the workpiece unit 100A or the like.

### Press Unit

Subsequently, the press unit 100B included in the resin sealing device 1 is described in detail. Here, FIG. 2 shows a front sectional view (schematic view) of the sealing mold 202 of the resin sealing device 1.

The press unit 100B includes the sealing mold 202. The sealing mold 202 includes a pair of dies (for example, those in which a plurality of blocks, plates, pillars or other members are assembled) that can be opened and closed. In the present embodiment, the pair of dies include the upper die 204 on an upper side in a vertical direction and the lower die 206 on a lower side in the vertical direction. The upper die 204 and the lower die 206 are configured to approach and separate from each other, thereby closing and opening the mold. That is, the vertical direction (up-down direction) is a mold opening/closing direction.

The sealing mold 202 is opened and closed by a known press device 250. For example, the press device 250 is configured to include: a pair of platens; a plurality of connecting mechanisms (tie bars or pillars), on which the pair of platens are constructed; and a drive source (for example, an electric motor) and a drive transmission mechanism (for example, a ball screw or a toggle link mechanism), moving (lifting or lowering) the platens, and the like (none shown). The sealing mold 202 is arranged between the pair of platens of the press device 250. In the present embodiment, the upper die 204 of a fixed type is assembled to a fixed platen (platen that is fixed to the connecting mechanism), and the lower die 206 of a movable type is assembled to a movable platen (platen that lifts and lowers along the connecting mechanism). However, the present invention is not limited to this configuration.

Next, the upper die 204 of the sealing mold 202 is described in detail. As shown in FIG. 2, the upper die 204 is configured to include an upper plate 222, a cavity block 226, a clamper 228, and the like, which are assembled together. In the present embodiment, a cavity 208 is provided on a lower surface (surface on the lower die 206 side) of the upper die 204.

More specifically, the cavity block 226 is fixedly assembled to a lower surface of the upper plate 222. On the other hand, the clamper 228 is configured in an annular shape to surround the cavity block 226, and is assembled while being spaced apart (floating) with respect to the lower surface of the upper plate 222 via an energization member 232 so as to be movable up and down. The cavity block 226 constitutes an inner part (bottom) of the cavity 208, and the clamper 228 constitutes a side part of the cavity 208. In the present embodiment, one upper die 204 is provided with one cavity 208. However, the present invention is not limited to this configuration. A configuration may be adopted in which a plurality of cavities are provided side by side in the left-right direction (or front-rear direction).

In the present embodiment, a suction mechanism is provided that suctions and holds the film F supplied from a film supply mechanism 214 (described later) onto the upper die 204. As an example, this suction mechanism communicates with a suction device (not shown) via suction paths 230a and 230b that are arranged through the clamper 228 as well as a suction path 230c that is arranged through the upper plate 222 and the cavity block 226. A seal member 234 (for example, an O-ring) is arranged between an inner peripheral surface of the clamper 228 and an outer peripheral surface of the cavity block 226.

In this way, by providing the film F that covers an inner surface of the cavity 208 and (a portion of) the mold surface 204a of the upper die 204, the resin R portion on an upper surface of the molded product Wp can be easily peeled off. Thus, it becomes possible to easily extract the molded product Wp from the sealing mold 202 (upper die 204).

In the present embodiment, an upper die heating mechanism is provided that heats the upper die 204 to a predetermined temperature. This upper die heating mechanism includes a heater (for example, a heating wire heater), a temperature sensor, a power supply or the like (none shown), in which heating control is performed by the control part 150. As an example, the heater is built in the upper plate 222 or a mold base (not shown) accommodating the above, and is configured to mainly apply heat to the entire upper die 204 and the resin R (described later). Accordingly, the upper die 204 is adjusted to a predetermined temperature (for example, 100° C. to 200° C.) and heated.

In the present embodiment, the film supply mechanism 214 is provided that conveys (supplies) the film F into the sealing mold 202, the film F being of a roll shape and having no openings (holes) in a sheet surface. The film supply mechanism 214 has the following configuration. The film F that has not been used is delivered from an unwinding section 214A and supplied to the sealing mold 202 that is opened. After being used for resin sealing in the sealing mold 202, the film F is wound up as the used film F in the winding section 214B. The unwinding section 214A and the winding section 214B may be arranged oppositely in the left-right direction (not shown).

Next, the lower die 206 of the sealing mold 202 is described in detail. As shown in FIG. 2, the lower die 206 is configured to include a lower plate 224, a holding plate 236, and the like, which are assembled together. Here, the holding plate 236 is fixedly assembled to an upper surface (surface on the upper die 204 side) of the lower plate 224.

In the present embodiment, a workpiece holder 205 is provided that holds the workpiece W in a predetermined position on an upper surface (that is, mold surface 206a) of the holding plate 236. As an example, the workpiece holder 205 communicates with a suction device (not shown) via a suction path 240a that is arranged through the holding plate 236 and the lower plate 224. In parallel to the configuration including the suction path 240a, a configuration (not shown) may be provided including a holding claw that clamps an outer periphery of the workpiece W.

In the present embodiment, corresponding to the above-mentioned configuration (configuration in which one cavity 208 is provided) of the upper die 204, one lower die 206 is provided with one workpiece holder 205, and the workpieces W are sealed with resin one by one. However, the present invention is not limited to this configuration.

In the present embodiment, a lower die heating mechanism is provided that heats the lower die 206 to a predetermined temperature. This lower die heating mechanism includes a heater (for example, a heating wire heater), a temperature sensor, a power supply or the like (none shown), in which heating control is performed by the control part 150. As an example, the heater is built in the lower plate 224 or a mold base (not shown) accommodating the above, and is configured to mainly apply heat to the entire lower die 206 and the workpiece W. Accordingly, the lower die 206 is adjusted to a predetermined temperature (for example, 100° C. to 200° C.) and heated.

The press unit 100B includes a workpiece heater 116 that heats the workpiece W conveyed by the loader 122 (details will be described later) from a lower surface side (base material Wa side) (a configuration without the workpiece heater 116 can also be adopted). The workpiece heater 116 according to the present embodiment is arranged in a predetermined position (in the present embodiment, a position where an in-loader section 124 of the loader 122 coincides with the sealing mold 202 in the left-right direction) in the left-right direction along a guide 120, and a lower position with respect to the loader 122 in the vertical direction.

As an example, the workpiece heater 116 includes a heating table 117 that has an upper surface formed in a planar shape and that is able to raise and maintain the temperature at a predetermined temperature. According to this configuration, a lower surface of the workpiece W can be brought into contact with the heating table 117 using the loader 122, and the workpiece W can be heated. Accordingly, the workpiece W can be preheated before being carried into the sealing mold 202. A known heating mechanism (for example, a heating wire heater or a sheathed heater) may be used as a mechanism that raises the temperature of the heating table 117.

Alternatively, as another example, the workpiece heater 116 may be configured to include an infrared heater or a heating wire heater on an upper surface, in which the workpiece W held by the loader 122 is heated in a non-contact manner (not shown).

### Molded Product Unit

Subsequently, the molded product unit 100C included in the resin sealing device 1 is described in detail.

As an example, the molded product unit 100C includes: an accommodation table 114, on which the molded product Wp is placed; and a molded product stocker 112, used for accommodating the molded product Wp. Accordingly, after the molded product Wp conveyed using the loader 122 is placed on the accommodation table 114 using a known pickup or the like (not shown), the molded product Wp is carried into the molded product stocker 112 using a known pusher or the like (not shown). A known stack magazine, slit magazine, or the like may be used for the molded product stocker 112, which is able to collectively accommodate a plurality of molded products Wp.

Alternatively, as another example, a configuration (not shown) may be adopted in which the molded product Wp is conveyed from the accommodation table 114 and is moved to another unit performing the next process using a moving device (such as a conveyor).

A configuration (not shown) may be adopted including an inspection mechanism that inspects an appearance of the molded product Wp in the molded product unit 100C or the like.

### Conveyance Mechanism

Subsequently, the conveyance mechanism 100D included in the resin sealing device 1 is described in detail.

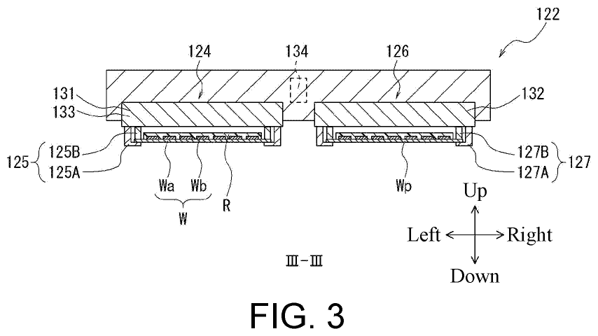

As an example, the conveyance mechanism 100D includes one loader 122 that is configured to be able to reciprocate in the left-right direction along the guide 120, and that carries the workpiece W and the resin R into the press unit 100B and carries out the molded product Wp from the press unit 100B. Here, FIG. 3 shows a front sectional view (sectional view taken along line III-III in FIG. 1) of the loader 122.

Specifically, the loader 122 includes: the in-loader section 124, holding the workpiece W; and the out-loader section 126, holding the molded product Wp. Accordingly, the loader 122 acts to receive the workpiece W (with the resin R placed thereon) in the workpiece unit 100A (for example, the supply table 104), and to convey the workpiece W to the press unit 100B. Furthermore, the loader 122 acts to receive the molded product Wp in the press unit 100B, and to convey the molded product Wp to the molded product unit 100C (for example, the accommodation table 114). A known pickup mechanism or the like may be used together as appropriate.

Here, the in-loader section 124 includes a workpiece holder 125 able to hold the workpiece W, and is configured to be movable in the front-rear direction with respect to a main body of the loader 122. Accordingly, the workpiece W (with the resin R placed thereon) held by the supply table 104 can be received and held by the workpiece holder 125, carried into the sealing mold 202 and placed on the lower die 206.

The out-loader section 126 includes a molded product holder 127 able to hold the molded product Wp, and is configured to be movable in the front-rear direction with respect to the main body of the loader 122. Accordingly, the molded product Wp held by the upper die 204 can be received and held by the molded product holder 127, carried out of the sealing mold 202, and placed on the accommodation table 114.

Furthermore, the in-loader section 124 and the out-loader section 126 are arranged in parallel (that is, side by side in the left-right direction) along the left-right direction, as shown in FIG. 1.

According to the loader 122 having the above configuration, the above-mentioned problems can be solved. That is, by the configuration of the loader 122 in which the in-loader section 124 and the out-loader section 126 are arranged side by side in the left-right direction, the molded product Wp can be carried out of the sealing mold 202 by the out-loader section 126 while the workpiece W is held in the in-loader section 124. After that, by simply moving the in-loader section 124 a little (that is, by about a distance between the centers of the in-loader section 124 and the out-loader section 126) to a position where it coincides with the sealing mold 202 in the left-right direction, the workpiece W can be carried into the sealing mold 202 by the in-loader section 124. Accordingly, compared to a conventional configuration, that is, a configuration in which carry-in of the workpiece and carry-out of the molded product are both performed by a single loader having a single holder, the takt time in a series of processes can be significantly shortened, and productivity can be improved. Particularly, as the number of press units 100B increases, greater effects can be achieved.

Furthermore, advantageous effects can be achieved over a conventional configuration in which a workpiece holding mechanism and a molded product holding mechanism are separately provided in a single loader. For example, compared to the conventional configuration in which the workpiece holding mechanism and the molded product holding mechanism are arranged in the front-rear direction of the loader, the device configuration can be reduced in size and be simplified, and the device cost can be reduced. Alternatively, compared to the conventional configuration in which the workpiece holding mechanism and the molded product holding mechanism are arranged on the upper surface and lower surface of the loader, mold opening/closing time can be shortened, and the takt time can be shortened. Particularly, if resin sealing (molding) is performed on the workpiece W of a large size using two or more press devices 250, the molding takes about 3 to 10 minutes. In this regard, according to the present embodiment, while molding is performed by one press device 250, carry-in of the workpiece W and carry-out of the molded product Wp in another press device 250 can be performed by a single loader 122. Thus, a configuration for separately and independently driving two loaders (an in-loader and an out-loader), for example, is not necessary. In this way, it is a great advantage that, while molding is performed by one press device 250, carry-in of the workpiece W and carry-out of the molded product Wp in another press device 250 can be performed. Accordingly, for example, even if three or more press devices are provided (not shown), by shifting timings at which a resin sealing process is performed in each press device, conveyance (carry-in of the workpiece W and carry-out of the molded product Wp) by a single loader becomes possible.

Here, as shown in FIG. 3, in the loader 122 according to the present embodiment, the workpiece holder 125 that holds the workpiece W is provided on a lower surface of the in-loader section 124, and the molded product holder 127 that holds the molded product Wp is provided on a lower surface of the out-loader section 126. For example, the workpiece holder 125 includes a chuck 125A and a support (such as a frame) 125B, and is configured to clamp the workpiece W; the molded product holder 127 includes a chuck 127A and a support (such as a frame) 127B, and is configured to clamp the molded product Wp. However, the present invention is not limited thereto. A configuration (not shown) may be adopted in which a suction hole is provided communicating with a suction device for suction. The workpiece holder 125 and the molded product holder 127 are configured to hold a single workpiece W and a single molded product Wp, respectively. However, the present invention is not limited thereto. The workpiece holder 125 and the molded product holder 127 may be configured to hold a plurality of workpieces W and a plurality of molded products Wp (not shown).

According to the above configuration, in the device configuration including the sealing mold 202 in which the cavity 208 is provided in the upper die 204 and the workpiece holder 205 is provided in the lower die 206, a configuration can be realized in which the workpiece holder 125 that holds the workpiece W and the molded product holder 127 that holds the molded product Wp are arranged in parallel in a single loader 122.

The loader 122 has the following configuration in order to preheat the workpiece W by the workpiece heater 116 arranged in the press unit 100B. Specifically, the loader 122 is configured so that the workpiece W (in this case, lower surface) held by the workpiece holder 125 of the in-loader section 124 is exposed toward the workpiece heater 116. According to this configuration, the workpiece W held by the workpiece holder 125 can be heated (preheated) by heat generated by the workpiece heater 116.

As described above, the workpiece heater 116 according to the present embodiment includes the heating table 117 that is brought into contact with and heats the lower surface of the workpiece W. Corresponding to this configuration, the loader 122 according to the present embodiment includes: a first lifting mechanism 131, lifting and lowering the in-loader section 124 (the entire in-loader section 124 or the workpiece holder 125); and a pressing mechanism 133, pressing the workpiece W held by the workpiece holder 125 of the in-loader section 124 against the workpiece heater 116 (in this case, upper surface of the heating table 117). According to this configuration, particularly in the case where the workpiece W is composed of a glass panel or the like, preheating can be performed while pressure is applied, and breakage of the workpiece W can be prevented. As a modification, the first lifting mechanism may also serve as the pressing mechanism, or the pressing mechanism may not be provided (not shown).

The pressing mechanism 133 is preferably configured so that a pressure that presses the workpiece W against the workpiece heater 116 is variable stepwise during pressing (in other words, the control part 150 is configured to control the pressure that presses the workpiece W against the workpiece heater 116 to be changed stepwise during pressing). Accordingly, since the workpiece W can be preheated while the pressure is changed stepwise, particularly with respect to the workpiece W composed of a glass panel as described above, breakage can further be prevented.

On the other hand, the loader 122 includes a second lifting mechanism 132 that lifts and lowers the out-loader section 126 (the entire out-loader section 126 or the molded product holder 127). Accordingly, the molded product Wp after resin sealing held by the sealing mold 202 (in this case, the upper die 204) can be received, held, and conveyed.

In the present embodiment, both the first lifting mechanism 131 and the second lifting mechanism 132 are configured to be driven by a single drive source (for example, the motor 134). According to this configuration, since the single motor 134 can be shared as the drive source by the first lifting mechanism 131 and the second lifting mechanism 132, the device structure can be simplified and the cost can be reduced. However, the present invention is not limited thereto. The first lifting mechanism 131 and the second lifting mechanism 132 may be configured to be respectively driven by different drive sources (not shown).

### Resin Sealing Operation

Subsequently, an operation of performing resin sealing using the resin sealing device 1 according to the present embodiment is described. Here, a configuration is described as an example in which a set of cavities 208 are provided in one upper die 204, one workpiece W is arranged in one lower die 206, and resin sealing is performed to obtain one molded product Wp. However, the present invention is not limited to this configuration. A configuration may be adopted in which a plurality of workpieces W are arranged and sealed with resin.

As a preparatory process, a heating process (upper die heating process) is performed by the upper die heating mechanism in which the upper die 204 is adjusted to a predetermined temperature (for example, 100° C. to 200° C.) and heated. A heating process (lower die heating process) is performed by the lower die heating mechanism in which the lower die 206 is adjusted to a predetermined temperature (for example, 100° C. to 200°° C.) and heated. Furthermore, by the film supply mechanism 214, a process (film supply process) is performed in which the film F is conveyed (delivered) from the unwinding section 214A to the winding section 214B, and is supplied to a predetermined position (position between the upper die 204 and the lower die 206) in the sealing mold 202.

Next, by a known pusher or the like (not shown), a process is performed in which the workpieces W are carried out one by one from the workpiece stocker 102 and placed on the supply table 104 (a known pickup mechanism or the like may be used together). Alternatively, as described above, a process may be performed in which the workpiece W is fed from a unit performing the previous process and is placed on the supply table 104.

Next, a process (resin supply process) is performed in which the resin R in a prescribed amount is supplied from a dispenser (not shown) onto the upper surface of the workpiece W placed on the supply table 104. The resin supply process may be performed on a separately provided resin spraying table (not shown) instead of on the supply table 104, or may be performed in a separate unit (for example, the unit performing the previous process).

Next, a process (workpiece conveyance process) is performed in which the workpiece W is conveyed to the press unit 100B by the loader 122. In detail, the loader 122 moves to a position where the in-loader section 124 coincides with the supply table 104 in the left-right direction. Next, the in-loader section 124 holds the workpiece W (on which the resin R is placed in the present embodiment) placed on the supply table 104. Next, the loader 122 moves to a position where the in-loader section 124 coincides with the workpiece heater 116 in the left-right direction (and also coincides with the sealing mold 202 in the left-right direction in the present embodiment). Next, in the loader 122 in a stopped state, the in-loader section 124 moves to a position where the workpiece holder 125 coincides with the workpiece heater 116 in the front-rear direction (alternatively, the workpiece holder 125 and the workpiece heater 116 may be set to coincide at a position where the loader 122 is stopped). Next, the first lifting mechanism 131 and the pressing mechanism 133 of the in-loader section 124 are driven, the workpiece W is lowered to bring the lower surface thereof into contact with the upper surface of the heating table 117 of the workpiece heater 116, a pressure (which may be changed stepwise) corresponding to the workpiece W is applied, and the workpiece W is preheated. At this time, the heating table 117 has been heated to a predetermined temperature corresponding to the workpiece W in advance. The above preheating process can also be omitted.

Next, a process (workpiece setting process) is performed in which the workpiece W is carried into the sealing mold 202 and set in the lower die 206 by the loader 122. In detail, the in-loader section 124 is moved to a position where the workpiece holder 125 coincides with the sealing mold 202 (lower die 206 in the present embodiment) in the front-rear direction. Next, the workpiece W held by the workpiece holder 125 of the in-loader section 124 is placed on the workpiece holder 205 in the lower die 206.

Next, the sealing mold 202 is closed, and a process (resin sealing process) is performed in which the workpiece W is clamped by the upper die 204 and the lower die 206 and sealed with resin. At this time, in the cavity 208, the cavity block 226 is relatively lowered, and the resin R is heated and pressurized against the workpiece W. Accordingly, the resin R is thermally cured, resin sealing (compression molding) is performed, and the molded product Wp is formed.

Here, in the present embodiment, while the resin sealing process is being performed, the second workpiece conveyance process is performed.

Next, the sealing mold 202 is opened, and a process (molded product extraction process) is performed in which the molded product Wp is extracted from the sealing mold 202 by the loader 122. In detail, the loader 122 moves to a position where the out-loader section 126 coincides with the sealing mold 202 in the left-right direction. Next, the out-loader section 126 moves to a position where the molded product holder 127 coincides with the sealing mold 202 (upper die 204 in the present embodiment) in the front-rear direction. Next, the molded product holder 127 of the out-loader section 126 receives and holds the molded product Wp held by the upper die 204. Next, the out-loader section 126 holding the molded product Wp moves to return to a predetermined accommodation position (frontmost position) in the loader 122. According to the above configuration, the molded product Wp can be carried out of the sealing mold 202 by the out-loader section 126 while the workpiece W is held by the in-loader section 124.

In parallel with (or after) the molded product extraction process, a process of delivering the film F that has been used is performed by the film supply mechanism 214 in which the film F is conveyed from the unwinding section 214A to the winding section 214B.

Here, in the present embodiment, after the molded product extraction process is performed, the second workpiece setting process is performed. At this time, by performing the molded product extraction process, the loader 122 is stopped in a position where the out-loader section 126 coincides with the sealing mold 202 in the left-right direction. As the second workpiece setting process is started, the loader 122 moves to a position where the in-loader section 124 coincides with the sealing mold 202 in the left-right direction. According to the above configuration, by simply moving the loader 122 a small distance (distance between the centers of the in-loader section 124 and the out-loader section 126) to the position where the in-loader section 124 coincides with the sealing mold 202, the workpiece W can be carried into the sealing mold 202 by the in-loader section 124. Accordingly, compared to a conventional configuration in which carry-in of the workpiece and carry-out of the molded product are both performed by a single loader having a single holder, the takt time in a series of processes can be significantly shortened, and productivity can be improved. Particularly, as the number of press units 100B increases, greater effects can be achieved.

Next, a process (molded product conveyance process) is performed in which the molded product Wp is conveyed to the molded product unit 100C by the loader 122. In detail, the loader 122 moves to a position where the out-loader section 126 holding the molded product Wp coincides with the accommodation table 114 in the left-right direction. Next, the out-loader section 126 places the molded product Wp on the accommodation table 114 (a known pickup mechanism or the like may be used together). A process of postcuring the molded product Wp or the like may be provided in the middle of the molded product conveyance process.

Next, a process is performed in which the molded product Wp is carried into the molded product stocker 112 by a known pusher or the like (not shown). Alternatively, as described above, a process may be performed in which the molded product Wp on the accommodation table 114 is delivered to the unit performing the next process.

The above are a series of resin sealing operations performed using the resin sealing device 1. However, the above processes are just an example, and the order of the processes can be changed or the processes can be performed in parallel as long as there is no problem. For example, in the present embodiment, since the configuration includes two press units 100B, efficient molded product formation is made possible by performing the above operations in parallel. Specifically, in the case of the present embodiment where there are arranged two press units 100B (that is, two press devices 250) and there is arranged one loader 122, the control part 150 performs control such that the resin sealing processes using the two press devices 250 respectively are performed in a temporally staggered manner (so as not to be at completely the same timing), and performs control such that carry-in of the workpiece W and carry-out of the molded product Wp with respect to the two press devices 250 using the one loader are performed in a temporally staggered manner (so as not to be at completely the same timing).

As described above, according to the resin sealing device according to the present invention, particularly by improving the efficiency in carry-in of the workpiece and carry-out of the molded product using a loader, the takt time in a series of resin sealing processes can be shortened and productivity can be improved. A device configuration can be simplified.

The present invention is not limited to the above embodiment, and may be modified in various ways without departing from the scope of the present invention. Particularly, while a compression molding device including a cavity in an upper die has been described as an example, the present invention is not limited thereto. For example, the present invention is also applicable to a configuration in which a workpiece is held on a loader and supplied to an upper die, and a molded product is extracted from the upper die. Furthermore, the present invention is also applicable to a resin sealing device or the like using a transfer molding method. The number of workpieces molded in one press is not limited to one.

1. resin sealing device, in which a workpiece is sealed with resin and processed into a molded product using a press device comprising a sealing mold that comprises an upper die and a lower die, wherein
the resin sealing device comprises a loader that reciprocates in a left-right direction along a guide and conveys the workpiece and the molded product;
the loader comprises: an in-loader section, configured to be movable in a front-rear direction and carrying the workpiece into the sealing mold; and an out-loader section, configured to be movable in the front-rear direction and carrying the molded product out of the sealing mold; and
the in-loader section and the out-loader section are arranged in parallel along the left-right direction.

2. The resin sealing device according to claim 1, wherein
the in-loader section comprises, on a lower surface, a workpiece holder that holds the workpiece; and
the out-loader section comprises, on a lower surface, a molded product holder that holds the molded product.

3. The resin sealing device according to claim 2, further comprising:
a workpiece heater, preheating the workpiece, wherein
the workpiece heater is arranged in a predetermined position along the guide and below the loader; and
the loader is configured so that the workpiece held by the workpiece holder of the in-loader section is exposed toward the workpiece heater.

4. The resin sealing device according to claim 3, wherein
the loader comprises: a first lifting mechanism, lifting and lowering the in-loader section; and a pressing mechanism, pressing the workpiece held by the workpiece holder of the in-loader section against the workpiece heater.

5. The resin sealing device according to claim 4, wherein
the pressing mechanism is configured so that a pressure that presses the workpiece against the workpiece heater is variable stepwise during pressing.

6. The resin sealing device according to claim 5, wherein
the loader comprises: a second lifting mechanism, lifting and lowering the out-loader section; and one motor, driving both the first lifting mechanism and the second lifting mechanism.

7. The resin sealing device according to claim 1, wherein
there are arranged two press devices;
there is arranged one loader;
the resin sealing device comprises a control part that controls operation of the press device and the loader; and
the control part performs control such that a resin sealing process in each of the two press devices is performed in a temporally staggered manner, and carry-in of the workpiece and carry-out of the molded product with respect to the two press devices are performed using the one loader.
